(19) United States
(12) Patent Application Publication
(10) Pub. No.: US 2013/0206958 A1
(43) Pub. Date: Aug. 15, 2013

(54) FIXING DEVICE FOR FAN

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/426,632

(22) Filed: Mar. 22, 2012

(30) Foreign Application Priority Data
Feb. 15, 2012 (CN) 201210033659.8

(51) Int. Cl. H05K 7/20; F16M 13/00

(52) U.S. Cl. 248/674

(57) ABSTRACT

A fixing device for fixing a fan includes a support and a number of fastening members. The fan includes a sidewall defining a number of fixing holes. The support includes a fixing plate defining a vent area and a number of slots located around the vent area. Each fastening member comprising an abutting portion detachably engaging in the corresponding slot, a stopping portion protruding from a first end of the abutting portion, and a latching portion extending out from a second end of the abutting portion opposite to the stopping portion. Each latching portion is latched into a corresponding one of the fixing hole of the fan, the stopping portion is abutted against an outer surface of the fixing plate distant from the fan.

### CROSS-REFERNECE OF RELATED APPALICATION

Relevant subject matter is disclosed in a pending U.S. patent application, titled “FIXING DEVICE FOR FAN”, with the application Ser. No. 13/403,926, filed on Feb. 23, 2012, which is assigned to the same assignee as this patent application.

### BACKGROUND

1. Technical Field

The present disclosure relates to fixing devices, and particularly to a fixing device for a fan such as a fan used in a computer system.

2. Description of Related Art

In a typical computer system, one or more fans are secured by screws or the like to an enclosure of the computer system. The fans are used for producing airflow to dissipate heat from electrical components within the enclosure, thus keeping the components operating under a desired temperature range. However, as computer systems become smaller in size, the components are more tightly arranged within the enclosure of the computer system. When the fans are secured to or removed from the enclosure, use of a screwdriver for screwing or unscrewing the screws may cause damage to the components, as there is not enough space for the screwdriver to maneuver within the enclosure of the computer system. In addition, the installation or removal of the screws is time consuming and troublesome.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is an exploded, isometric view of part of an electronic device which employs an exemplary embodiment of a fixing device, wherein the fixing device includes an L-shaped support and a plurality of fixing members.

FIG. 2 is similar to FIG. 2, but viewed from another perspective.

FIG. 3 is an enlarged view of one of the fixing members of FIG. 1.

FIG. 4 is an assembled view of FIG. 2.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references can mean “at least one.”

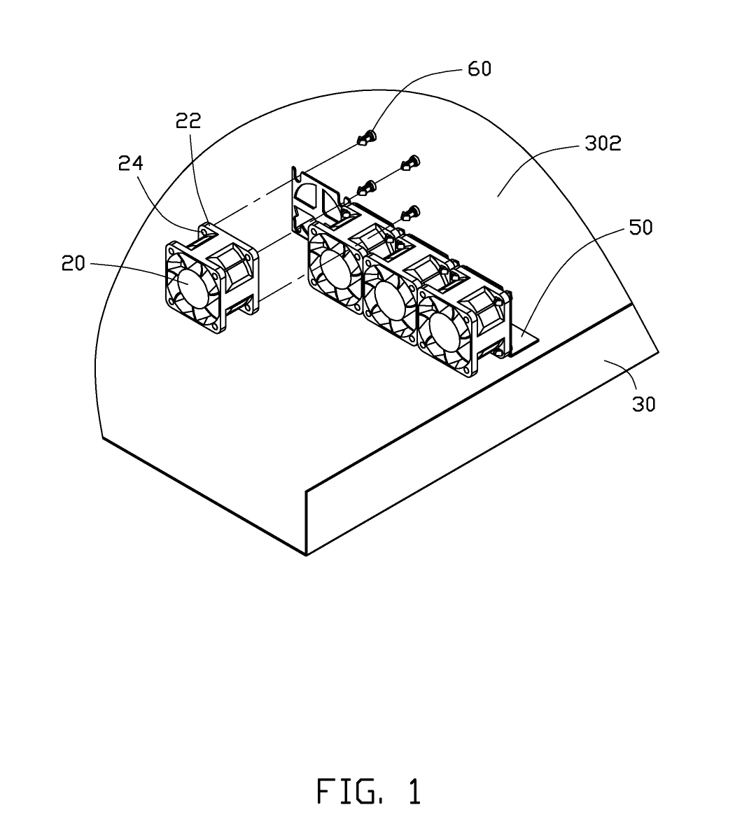

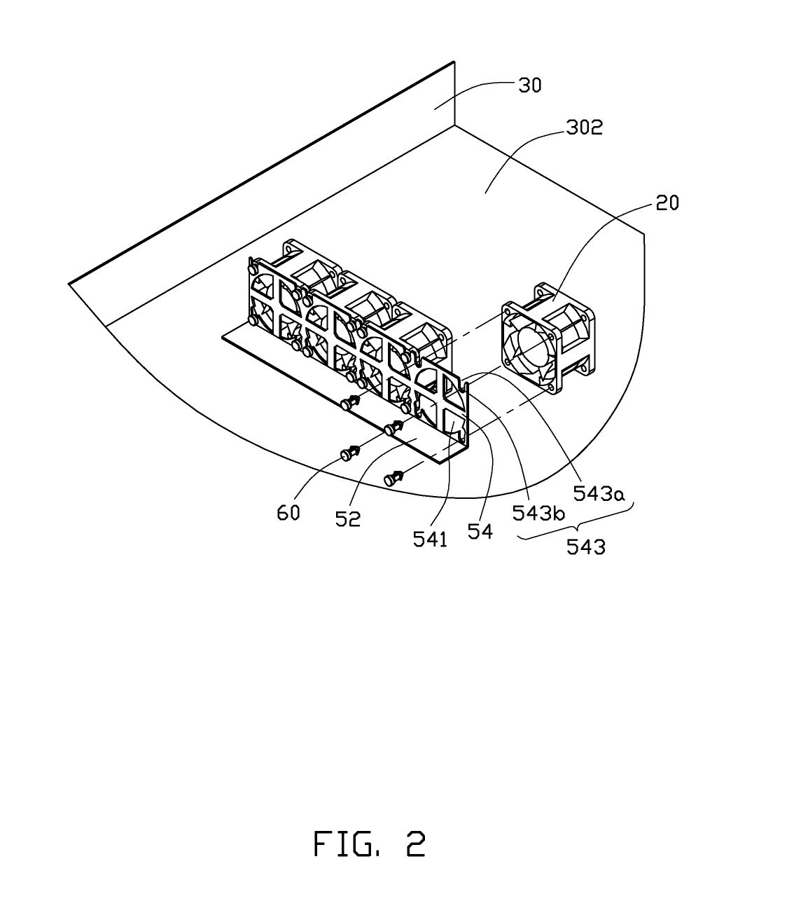

Referring to FIGS. 1 and 2, aspects of an exemplary embodiment of a fixing device are shown. The fixing device is used for fixing one or more fans 20 in an electronic device 30. Each fan 20 includes two opposite sidewalls 22. Four corners of each sidewall 22 each define four fixing holes 24. The electronic device 30 includes a bottom wall 302. The fixing device includes an L-shaped support 50 and a plurality of fastening members 60.

The support 50 includes a mounting plate 52 secured to the bottom wall 302, and a fixing plate 54 perpendicularly extending up from the mounting plate 52. A plurality of vent areas 541 is defined in the fixing plate 54, with the vent areas 541 aligned along the lengthwise direction of the fixing plate 54. Each vent area 541 includes a plurality of through holes. The fixing plate 54 defines a plurality of slots 543, each slot 543 being adjacent to a respective corner of a respective vent area 541. Each slot 543 at each top corner of each of the vent areas 541 includes a guiding portion 543a extending through the top edge of the fixing plate 54, and a holding portion 543b extending down from a bottom end of the guiding portion 543a. Each slot 543 at each bottom corner of each of the vent areas 541 is similar to each slot 543 at each top corner of each of the vent areas 541, and includes a guiding portion 543a communicating with a corresponding one of the through holes of the vent area 541, and a holding portion 543b extending down from a bottom end of the guiding portion 543a. A width of each guiding portion 543a is larger than a width of the corresponding holding portion 543b.

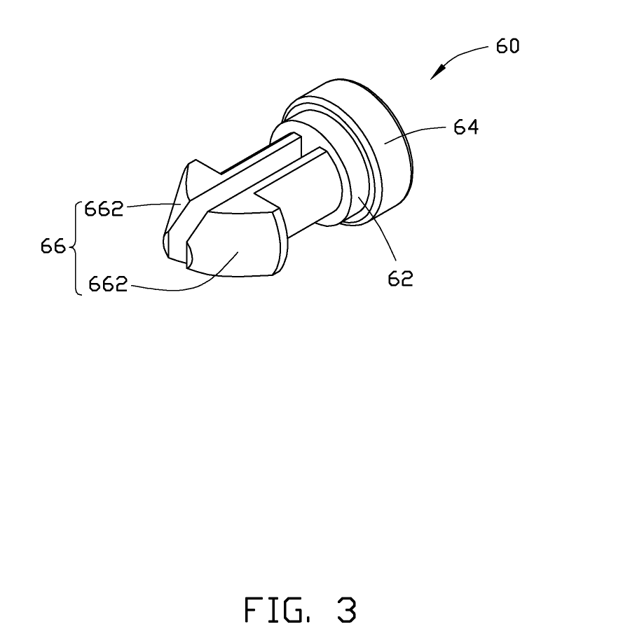

Referring to FIG. 3, each fastening member 60 includes a cylindrical abutting portion 62, a cylindrical stopping portion 64 extending out from a first end of the abutting portion 62, and a latching portion 66 extending out from a second end of the abutting portion 62 opposite to the stopping portion 64. The latching portion 66 includes two opposite resilient hooks 662 extending out from the abutting portion 62. A diameter of the abutting portion 62 is less than a diameter of the stopping portion 64, the diameter of the abutting portion 62 is larger than the corresponding fixing hole 24.

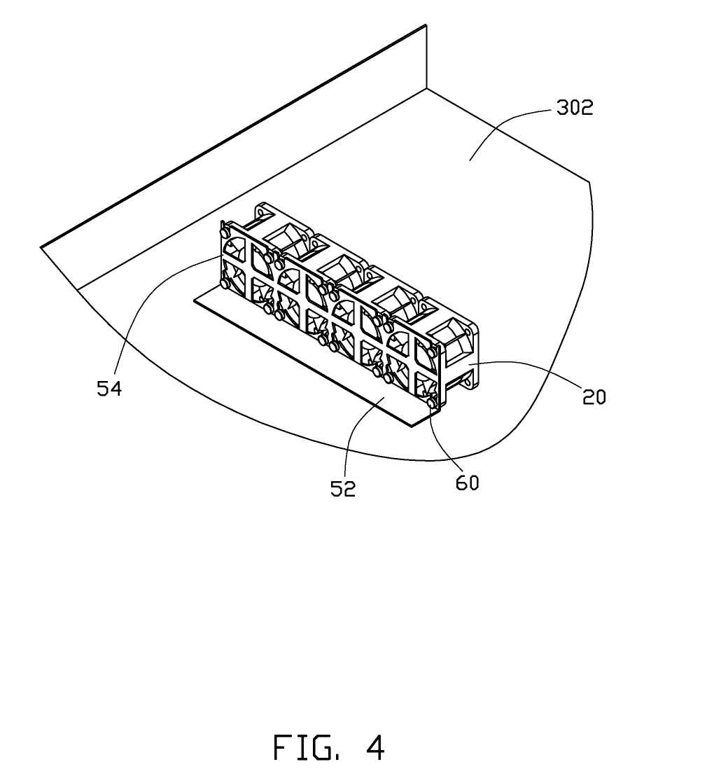

Referring also to FIG. 4, in assembly of the four fastening members 60 to each fan 20, the hooks 662 of each fastening member 60 are deformed toward each other. The deformed hooks 662 are inserted into a corresponding fixing hole 24 from an outer side of one of the sidewalls 22, until distal ends of the hooks 662 pass through the fixing hole 24. The hooks 662 are self-restored and snappingly engage with an inner surface of the sidewall 22. The abutting portion 62 of each fastening member 60 is inserted into the holding portion 543b of the corresponding slot 543 through the corresponding guiding portions 543a. The stopping portions 64 abut against an outer surface of the fixing plate 54 distant from the fan 20. The fan 20 is thus securely attached on the fixing plate 54, and is aligned with a corresponding vent area 541.

The combination of the fan 20 and the fastening members 60 is detached from the L-shaped support 50 by disengaging the abutting portions 62 from the corresponding slots 543. The combination of the fan 20 and the fastening members 60 then can be easily removed from the fixing plate 54.

While the disclosure describes examples and embodiments, it is to be understood that the disclosure is not limited thereto. To the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A fixing device for fixing a fan thereon, the fan comprising a sidewall, and the sidewall defining a plurality of fixing holes, the fixing device comprising:
a support comprising a fixing plate, the fixing plate defining a vent area and a plurality of slots located around the vent area; and
a plurality of fastening members, each fastening member comprising an abutting portion detachably engaging in the corresponding slot, a stopping portion protruding from a first end of the abutting portion, and a latching portion extending out from a second end of the abutting portion opposite to the stopping portion, wherein each latching portion is latched into a corresponding one of the fixing holes of the fan, the stopping portion is abutted against an outer surface of the fixing plate distant from the fan.

2. The fixing device of claim 1, wherein each slot above the vent area comprises a first guiding portion extending through a top edge of the fixing plate, and a first holding portion extending down from a bottom end of the first guiding portion, each slot below the vent area comprises a second guiding portion communicating with the vent area and a second holding portion extending down from a bottom end of the second guiding portion, and each abutting portion is detachably inserted into the corresponding one of the first and second holding portions through the corresponding one of the first and second guiding portions.

3. The fixing device of claim 2, wherein each latching portion comprises two opposite resilient hooks extending out from the abutting portion, the hooks extend through the corresponding fixing hole, to latch an inner surface of the sidewall of the corresponding fan opposite to the fixing plate.

4. The fixing device of claim 2, wherein the abutting portion and the stopping portion of each fastening member are cylindrical, a diameter of the abutting portion is less than a diameter of the stopping portion, the diameter of the abutting portion is larger than the corresponding fixing hole.

5. The fixing device of claim 1, wherein the support further comprises a mounting plate extending from the fixing plate for mounting the support to an electronic device.

6. A fixing device for fixing a plurality of fans thereon, each fan comprising a sidewall and the sidewall defining a plurality of fixing holes, the fixing device comprising:
a support comprising a fixing plate, the fixing plate defining a plurality of vent areas and a plurality of slots located around each vent area; and
a plurality of fastening members, each fastening member comprising an abutting portion detachably engaging in a corresponding one of the slots, a stopping portion protruding from a first end of the abutting portion, and a latching portion extending out from a second end of the abutting portion opposite to the stopping portion, wherein each latching portion is latched into a corresponding one of the fixing holes of a corresponding one of the fans, the stopping portion is abutted against an outer surface of the fixing plate distant from the corresponding fan.

7. The fixing device of claim 6, wherein each slot above the corresponding vent area comprises a first guiding portion extending through a top edge of the fixing plate, and a first holding portion extending down from a bottom end of the first guiding portion, each slot below the corresponding vent area comprises a second guiding portion communicating with the vent area and a second holding portion extending down from a bottom end of the second guiding portion, and each abutting portion is detachably inserted into the corresponding one of the first and second holding portions through the corresponding one of the first and second guiding portions.

8. The fixing device of claim 7, wherein each latching portion comprises two opposite resilient hooks extending out from the abutting portion, the hooks extend through the corresponding fixing hole, to latch an inner surface of the sidewall of the corresponding fan opposite to the fixing plate.

9. The fixing device of claim 7, wherein the abutting portion and the stopping portion of each fastening member are cylindrical, a diameter of the abutting portion is less than a diameter of the stopping portion, the diameter of the abutting portion is larger than the corresponding fixing hole.

10. The fixing device of claim 6, wherein the support further comprises a mounting plate extending from the fixing plate for mounting the support to an electronic device.
